(19) United States
(12) Patent Application Publication
(10) Pub. No.: US 2020/0343120 A1
(43) Pub. Date: Oct. 29, 2020

(54) HEATER BASE AND PROCESSING APPARATUS

(71) Applicant: ULVAC, INC., Chigasaki-shi (JP)

(72) Inventors: Takehisa MIYAYA, Chigasaki-shi (JP); Yosuke JIMBO, Chigasaki-shi (JP); Yoshiaki YAMAMOTO, Chigasaki-shi (JP); Kenji ETO, Chigasaki-shi (JP); Yoichi ABE, Chigasaki-shi (JP)

(21) Appl. No.: 16/480,540

(22) PCT Filed: Jan. 16, 2019
(86) PCT No.: PCT/JP2019/001049

§ 371 Date: Jul. 24, 2019

(30) Foreign Application Priority Data
Jan. 19, 2018 (JP) 2018-007451

(51) Int. Cl. H01L 21/683; H01L 21/31; H01L 21/67; H05H 1/46

(52) U.S. Cl. CPC H01L 21/683; H01L 21/31; H05H 1/46; H01L 21/67259; H01L 21/67288; H01L 21/67103

(57) ABSTRACT

A heater base of the invention includes a plurality of displacement mechanisms that are arranged between the heater and the heater base and are provided on the heater base. Of the displacement mechanisms, three or more displacement mechanisms are capable of displacing the heater with respect to the heater base in a state of being in contact with the heater.

### TECHNICAL FIELD

The present invention relates to a heater base and a processing apparatus.

This application claims priority from Japanese Patent Application No. 2018-7451 filed on Jan. 19, 2018, the contents of which are incorporated herein by reference in their entirety.

### BACKGROUND ART

Conventionally, a configuration that includes a heater base that supports a back surface of a heater heating the substrate is known as a processing apparatus that processes a substrate. From the viewpoint of thermal conductivity or corrosion resistance, metal such as an aluminum alloy is used as a material used to form the heater. A material such as ceramic is adopted as a material used to form the heater base.

### PRIOR ART DOCUMENTS

### Patent Documents

### (Patent Document 1) Japanese Unexamined Patent Application, First Publication No. 2008-244079

### SUMMARY OF THE INVENTION

### Problems to be Solved by the Invention

In the case of applying the aforementioned configuration to a film formation apparatus, a temperature of the heater during film formation becomes a high temperature, for example, 200 to 480° C. or the like. Under such a high temperature, due to difference in coefficient of thermal expansion between the constituent materials of the heater and the heater base, the heater thermally expands relative to the heater base.

When the temperature of the heater becomes high (for example, at a high temperature such as over 380° C.), friction is likely to occur at the contact face between an aluminum alloy forming the heater and ceramic forming the heater base, and the heater is less likely to slide on the heater base. In this case, waviness deformation (wavelike deformation) or warpage deformation due to the friction on the contact face occurs in accordance with thermal expansion in the horizontal direction of the heater, and therefore flatness of the top surface of the heater is degraded. As a result, there is a problem in that a gap between an upper electrode facing the heater and the heater becomes non-uniform, and a uniform film thickness profile is not obtained.

In recent years, since the heater and the heater base become larger in size with an increase in processing apparatus in size, an amount of thermal expansion of the heater increases due to the aforementioned difference in coefficient of thermal expansion, and furthermore a deformation amount due to waviness or warpage due to friction also increases.

The invention was made in view of the above-described situation, and has an object to provide a heater base that prevents waviness or warpage of a heater and can maintain flatness of the heater and a processing apparatus provided with the heater base.

### Means for Solving the Problems

A heater base according to a first aspect of the invention, includes: a plurality of displacement mechanisms that are arranged between the heater and the heater base and are provided on the heater base. Of the displacement mechanisms, three or more displacement mechanisms are capable of displacing the heater with respect to the heater base in a state of being in contact with the heater.

In the heater base according to the first aspect of the invention, each of the displacement mechanisms may include: a pedestal that is fixed to the heater base and has a recessed portion, the recessed portion opening toward the heater; a plurality of small-diameter balls that are located inside the recessed portion and roll on a surface of the recessed portion; and a large-diameter ball that is rotatably supported by the small-diameter balls inside the recessed portion, is in contact with the heater, and has a diameter larger than that of the small-diameter ball.

In the heater base according to the first aspect of the invention, each of the displacement mechanisms may include: a plurality of the recessed portions; and a plurality of the large-diameter balls, wherein one large-diameter ball may be disposed in one recessed portion.

In the heater base according to the first aspect of the invention, the displacement mechanisms may be arranged on one surface of the heater base.

In the heater base according to the first aspect of the invention, the heater base includes: a first base that extends in a first direction; and a plurality of second bases that extend in a second direction intersecting with the first direction and are fixed to the first base, wherein the displacement mechanisms may be arranged on the second bases.

In the heater base according to the first aspect of the invention, the displacement mechanism may be arranged on the first base.

In the heater base according to the first aspect of the invention, the heater base includes: a flat plate-shaped first base; and a flat plate-shaped second base that has a center coinciding with a center of the first base when seen in a plan view of the heater base, has an outer-periphery located outside an outer-periphery of the first base, is disposed on an upper surface of the first base so as to cover an entire surface of the first base, and is configured of a plurality of base separated bodies, wherein the displacement mechanisms may be arranged on the base separated bodies.

In the heater base according to the first aspect of the invention, the heater base includes a plurality of distance adjusters on a surface of the heater base on which the displacement mechanisms are arranged, one displacement mechanism is disposed on one distance adjuster, a distance between a contact portion at which the displacement mechanism is in contact with the heater and the heater base may be adjusted for each of the distance adjusters.

In the heater base according to the first aspect of the invention, a distance between the distance adjuster located at an outer-peripheral region of the surface of the heater base and the heater may be determined to be greater than a distance between the distance adjuster located at a center region of the surface and the heater.

The heater base according to the first aspect of the invention further includes a spacer provided on the distance adjuster, wherein a distance between the distance adjuster and the heater may be determined in accordance with a height of the spacer.

A processing apparatus according to a second aspect of the invention which is a processing apparatus processing a substrate and includes: a chamber; a heater that has a top surface on which the substrate to be mounted and a back surface on a side opposite to the top surface and is disposed inside the chamber; a heater base that supports the back surface of the heater and is disposed inside the chamber; a plurality of displacement mechanisms that are arranged between the heater and the heater base and are provided on the heater base; a high-frequency power supply that generates plasma inside the chamber; and a lifting mechanism that moves the heater base in a vertical direction, wherein of the displacement mechanisms, three or more displacement mechanisms are capable of displacing the heater with respect to the heater base in a state of being in contact with the heater.

### Effects of the Invention

According to the above-described aspects, waviness or warpage of a heater is prevented and it is possible to maintain flatness of the heater.

### BRIEF DESCRIPTION OF THE DRAWINGS

FIG. 1 is a cross-sectional view showing a schematic configuration of a processing apparatus according to a first embodiment of the invention.

FIG. 2A is an enlarged cross-sectional view showing a heater, a heater base, and a ball bearing unit which constitute the processing apparatus according to the first embodiment of the invention.

FIG. 2B is an enlarged cross-sectional view showing the heater, the heater base, and the ball bearing unit which constitute the processing apparatus according to a modified example A of the first embodiment of the invention.

FIG. 2C is an enlarged cross-sectional view showing the heater, the heater base, and the ball bearing unit which constitute the processing apparatus according to a modified example B of the first embodiment of the invention.

FIG. 3 is a view showing the processing apparatus according to the first embodiment of the invention which is projected thereon from a vertical direction and is a plan view for explaining a configuration of the heater, the heater base, and the ball bearing unit which constitute the processing apparatus.

FIG. 4A is an enlarged cross-sectional view showing a modified example C of a ball bearing unit which constitutes the processing apparatus according to the first embodiment of the invention.

FIG. 4B is an enlarged plan view showing the modified example C of the ball bearing unit which constitutes the processing apparatus according to the first embodiment of the invention.

FIG. 4C is an enlarged plan view showing a modified example D of a ball bearing unit which constitutes the processing apparatus according to the first embodiment of the invention.

FIG. 5A is view showing a processing apparatus according to a second embodiment of the invention which is projected thereon from a vertical direction, is an explanatory diagram showing a configuration of a heater, a heater base, and ball bearing units which constitute the processing apparatus, and is a plan view showing the heater base.

FIG. 5B is a view showing the processing apparatus according to the second embodiment of the invention which is projected thereon from a vertical direction, is an explanatory diagram showing a configuration of the heater, the heater base, and the ball bearing units which constitute the processing apparatus, and is a plan view showing a modified example 1 of the heater base.

FIG. 6A is a view showing the processing apparatus according to the second embodiment of the invention which is projected thereon from a vertical direction, is an explanatory diagram showing a configuration of the heater, the heater base, and the ball bearing units which constitute the processing apparatus, and is a plan view showing a modified example 2 of the heater base.

FIG. 6B is a view showing the processing apparatus according to the second embodiment of the invention which is projected thereon from a vertical direction, is an explanatory diagram showing a configuration of the heater, the heater base, and the ball bearing units which constitute the processing apparatus, and is a plan view showing a modified example 3 of the heater base.

FIG. 7A is an explanatory diagram showing a plane pattern of the ball bearing units when seen in a plan view of the heater base constituting the processing apparatus according to the second embodiment of the invention, and is a view showing a modified example 4.

FIG. 7B is an explanatory diagram showing a plane pattern of the ball bearing units when seen in a plan view of the heater base constituting the processing apparatus according to the second embodiment of the invention, and is a view showing a modified example 5.

FIG. 8A is an explanatory diagram showing a plane pattern of the ball bearing units when seen in a plan view of the heater base constituting the processing apparatus according to the second embodiment of the invention, and is a view showing a modified example 6.

FIG. 8B is an explanatory diagram showing a plane pattern of the ball bearing units when seen in a plan view of the heater base constituting the processing apparatus according to the second embodiment of the invention, and is a view showing a modified example 7.

FIG. 9 is an explanatory diagram showing a configuration of an upper electrode, a heater, a heater base, and ball bearing units which constitute a processing apparatus according to a third embodiment of the invention, and is a partial cross-sectional view showing the processing apparatus.

### EMBODIMENTS FOR CARRYING OUT THE INVENTION

A heater base and a processing apparatus according to embodiments of the invention will described with reference to drawings. In the respective drawings used for explanation of the embodiment, individual members are enlarged so as to be recognizable, and thus the reduced scales of the individual members are appropriately changed. In the explanation of the embodiments, “when seen in a plan view” means a plan view showing members which constitute the processing apparatus from the vertical direction (upward and downward directions, direction of gravitational force). Additionally, the horizontal direction (X-direction and Y-direction) means the directions orthogonal to the vertical direction.

### First Embodiment

### (Processing Apparatus)

In the following explanation, as an example, the case will be described where the processing apparatus according to the first embodiment of the invention is applied to a plasma CVD apparatus (Chemical Vapor Deposition).

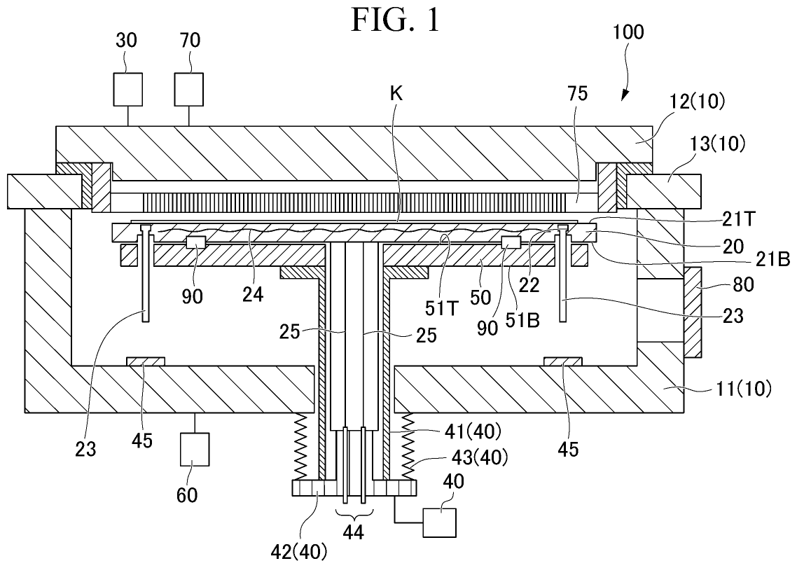

FIG. 1 is a cross-sectional view showing a schematic configuration of a plasma CVD apparatus 100 according to the first embodiment of the invention.

As shown in FIG. 1, the plasma CVD apparatus 100 includes a vacuum chamber 10, a heater 20, a high-frequency power supply 30, a lifting mechanism 40, a heater base 50, a vacuum pump 60, a gas supplier 70, and a door valve 80.

### (Vacuum Chamber)

The vacuum chamber 10 includes a lower chamber 11, an upper chamber 12, and an electrode flange 13 that is held between the lower chamber 11 and the upper chamber 12.

### (Heater)

The heater 20 is disposed inside the vacuum chamber 10 and is formed of an aluminum alloy serving as an electroconductive member. The heater 20 has: a mounting surface 21T (top surface) on which a substrate K is to be mounted; a support surface 21B (back surface, the back surface on the opposite side of the top surface) that faces the heater base 50 and is supported by a plurality of ball bearing units 90 (which will be described below).

The heater 20 has a plurality of opening holes 22 that are formed thereon, penetrate through the heater 20, and open at the mounting surface 21T. A lift pin 23 is housed inside each of the opening holes 22, and the lift pin 23 is capable of moving up and down in the vertical direction inside the opening hole 22.

A heater line 24 is provided inside the heater 20. The heater line 24 has a predetermined plane pattern when seen in a plan view of the heater 20, and terminals of the heater line 24 are exposed at the support surface 21B. The terminals of the heater line 24 are connected to electric supply lines 25 provided inside a support pillar 41 constituting the lifting mechanism 40. The electric supply lines 25 are connected to external terminals 44 that are provided on a flange 42 constituting the lifting mechanism 40.

### (High-Frequency Power Supply)

The high-frequency power supply 30 is provided outside the vacuum chamber 10 and is electrically connected, via a matching box and a wiring which are not shown in the figure, to an upper electrode 75 (cathode electrode) provided inside the vacuum chamber 10. When the high-frequency power supply 30 is activated, matched high-frequency power (RF) is supplied to the upper electrode 75, and therefore plasma is generated inside the vacuum chamber 10.

### (Lifting Mechanism)

The lifting mechanism 40 includes a driving device such as a motor, a power transmission mechanism such a gear, the support pillar 41, the flange 42, and a bellows 43.

The support pillar 41 is surrounded by the bellows 43, is disposed inside the vacuum chamber 10, and fixed to the flange 42 and a back surface 51B of the heater base 50. The bellows 43 is extendable in the vertical direction and is fixed to a lower surface of the vacuum chamber 10 and an upper surface of the flange 42.

The lifting mechanism 40 includes a driving device such as a motor, a power transmission mechanism such a gear, and can move the flange 42 in the vertical direction. The support pillar 41 fixed between the flange 42 and the heater base 50 moves due to movement of the flange 42 in the vertical direction, and therefore the heater 20 moves in the vertical direction inside the vacuum chamber 10. That is, the lifting mechanism 40 can change a position of the heater 20 in the vertical direction and can appropriately adjust a gap between the heater 20 and the upper electrode 75. For example, it is possible to set a narrow gap, for example, 14 mm.

Note that, the lift pins 23 come into contact with lift pin bases 45 due to downward movement of the heater 20 and therefore the lift pins 23 protrude from the mounting surface 21T. At this time, in the case where the substrate K is mounted on the mounting surface 21T, the lift pins 23 raise the substrate K, and thereafter the substrate K is transferred to the outside of the vacuum chamber 10 by a transfer arm which is not shown in the figure.

### (Vacuum Pump)

The vacuum pump 60 is connected to exhaust ports via a pressure adjustment valve and a pipe which are not shown in the figure and which are formed at the vacuum chamber 10. By driving the vacuum pump 60, it is possible to maintain the inside of the vacuum chamber 10 to be in a vacuum state, and a gas that remains inside the vacuum chamber 10 after a process is completed can be removed. In addition, as the vacuum pump 60 and the pressure adjustment valve are driven in the case where a processing gas is supplied to the inside of the vacuum chamber 10, the pressure inside the vacuum chamber 10 can be adjusted depending on process conditions.

### (Gas Supplier)

The gas supplier 70 is connected to a gas supply hole formed on the vacuum chamber 10 via a mass-flow controller and a pipe which are not shown in the figure. The types of gases supplied from the gas supplier 70 can be appropriately selected depending on the types of processes inside the vacuum chamber 10, for example, film formation processing, etching processing, ashing processing, or the like. After the gas supplied from the gas supplier 70 is supplied to the vacuum chamber 10, the gas passes through the upper electrode 75 (shower plate) and is supplied toward the substrate K and to a space between the upper electrode 75 and the heater 20.

### (Door Valve)

The door valve 80 includes an open-close drive mechanism which is not shown in the figure. When the door valve 80 opens, a transfer arm which is not shown in the figure can transfer the substrate K to the inside of the plasma CVD apparatus 100 or can transfer the substrate K from the plasma CVD apparatus 100. When the door valve 80 closes, the vacuum chamber 10 becomes in a hermetically-closed state, and the substrate K can be processed inside the vacuum chamber 10.

The plasma CVD apparatus 100 may include a cleaning device that cleans surfaces of members inside the vacuum chamber 10 by supplying a gas such as NF₃ to a discharge space inside the vacuum chamber 10. As such cleaning device, a device using remote plasma is adopted.

### (Heater Base)

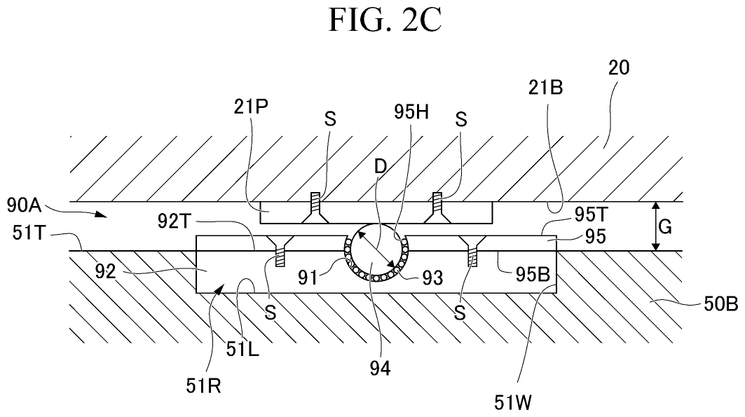

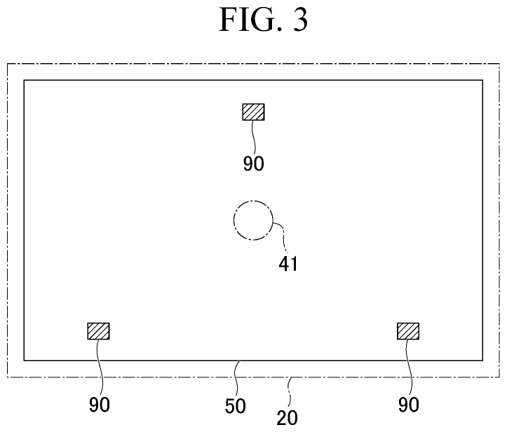

The heater base 50 is disposed inside the vacuum chamber 10 and supports the support surface 21B of the heater 20. A plurality of ball bearing units 90 (displacement mechanism) which will be described later are arranged between the heater 20 and the heater base 50, and the ball bearing units 90 are provided on an upper surface 51T of the heater base 50. As a material used to form the heater base 50, ceramic is adopted. In the embodiment, the shape of the heater base 50 is a flat plate shape and is a rectangular shape as shown in FIG. 3 when seen in a plan view. Note that, although a shape of the heater base 50 when seen in a plan view is a rectangular shape, a shape of the heater base 50 is not limited to the embodiment.

### (Ball Bearing Unit)

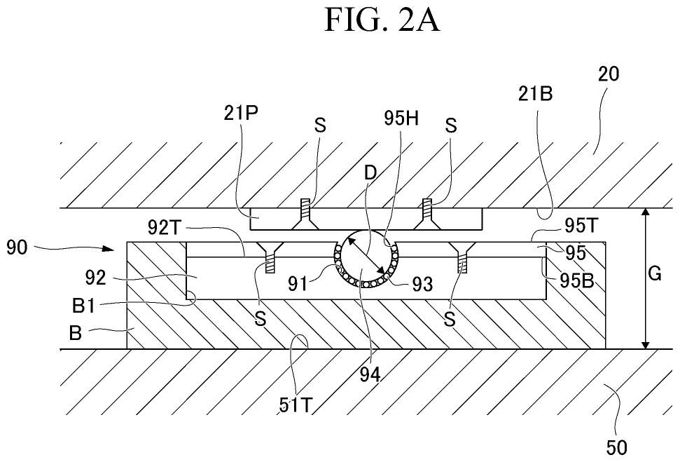

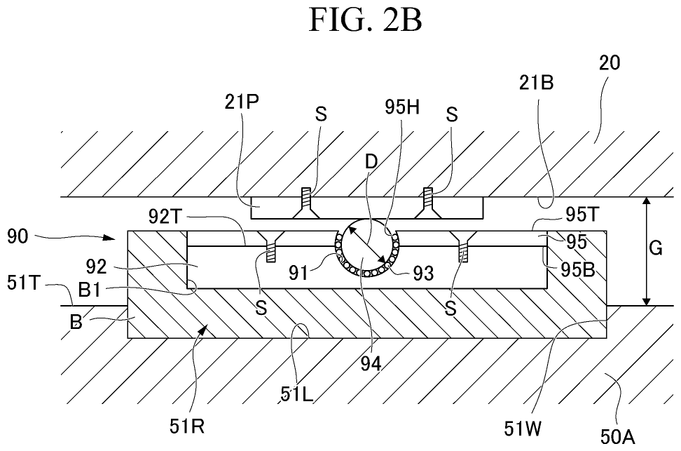

FIG. 2A is an enlarged cross-sectional view showing the heater 20, the heater base 50, and the ball bearing unit 90 which are shown in FIG. 1.

Each of the ball bearing units 90 includes a base plate B, a pedestal 92, a plurality of small-diameter balls 93, a large-diameter ball 94, and a cover 95.

### (Base Plate)

The base plate B is fixed to the upper surface 51T of the heater base 50 by fastening members which is not shown in the figure. The base plate B is provided with a container B1 to which the pedestal 92 is fixed.

A shape of the container B1 appropriately selected depending on a shape of the pedestal 92. A material used to form the base plate B is, for example, aluminum. A thickness of the base plate B at the container B1 is appropriately determined such that the distance between the heater 20 and the heater base 50 at the portion at which the ball bearing unit 90 is disposed is equal to each other over the entire surface of the heater base 50.

### (Pedestal)

The pedestal 92 is accommodated in the container B1 of the base plate B. A recessed portion 91 formed on the pedestal 92 is, for example, a hemispherical-shaped recess and opens toward the heater 20. A spherical surface (curved surface) is formed inside the recessed portion 91.

### (Small-Diameter Ball)

The small-diameter balls 93 are located inside the recessed portion 91 and are disposed along the spherical surface of the recessed portion 91. The small-diameter balls 93 can roll on the surface of the recessed portion 91.

In the embodiment, a diameter of the small-diameter ball 93 is, for example, 2.0 mm, and the number of the small-diameter balls 93 is, for example, 49 to 52.

Note that, the number and the diameter of the small-diameter balls 93 are not limited to the embodiment. The number and the diameter of the small-diameter balls 93 are appropriately determined in consideration of ease of roll of the small-diameter balls 93, a diameter of the large-diameter ball 94, ease of roll of the large-diameter ball 94, heights of the pedestal 92 and the cover 95, a distance between the heater 20 and the heater base 50, prevention of the small-diameter balls 93 from being removed from the ball bearing unit 90, or the like.

### (Large-Diameter Ball)

The large-diameter ball 94 is supported by the small-diameter balls 93 inside the recessed portion 91, is in contact with a pad 21P (contact portion) of the heater 20, and has a diameter larger than that of the small-diameter ball 93.

The large-diameter ball 94 can roll on the surfaces of the small-diameter balls 93 in a state of being in contact with a portion of the spherical surface of each of the small-diameter balls 93.

In the embodiment, one large-diameter ball 94 is disposed inside one recessed portion 91.

In the embodiment, a diameter of the large-diameter ball 94 is, for example, 9.5 mm.

Note that, the diameter of the large-diameter ball 94 is not limited to the embodiment. The diameter of the large-diameter ball 94 is appropriately determined in consideration of ease of roll of the large-diameter ball 94, heights of the pedestal 92 and the cover 95, a distance between the heater 20 and the heater base 50, prevention of the large-diameter ball 94 from being removed from the ball bearing unit 90, or the like.

### (Pad)

The pad 21P is a member fixed to the support surface 21B of the heater 20 by fastening members S such as a screw, and the position of the pad 21P corresponds to the position of the large-diameter ball 94. The pad 21P is in contact with a portion of the spherical surface of the large-diameter ball 94, and the large-diameter ball 94 can roll on the surface of the pad 21P.

The area of the pad 21P is appropriately determined so that the large-diameter ball 94 is not dropped off from the pad 21P when the heater 20 is displaced relative to the heater base 50. In other words, the area of the pad 21P is appropriately determined so as to maintain a contact state between the pad 21P and the large-diameter ball 94.

Note that, the pad 21P constitutes a part of the heater 20 and a configuration of the heater 20 including the pad 21P may be referred to as “heater” in the embodiment. Additionally, the contact face on which the pad 21P comes into contact with the large-diameter ball 94 may be referred to as a back surface of the heater 20.

Moreover, “a state where the ball bearing unit 90 is in contact with the heater 20 (displacement mechanism is in contact with the heater” means a state where the heater 20 and the large-diameter ball 94 (ball bearing unit 90) are disposed with the pad 21P interposed therebetween or means a state where the heater 20 directly comes into contact with the large-diameter ball 94 without interposing the pad 21P therebetween.

### (Cover)

The cover 95 is fixed to an upper surface 92T of the pedestal 92 by fastening members S such as a screw. A circular hole 95H is formed on the cover 95, and the large-diameter ball 94 is disposed inside the hole 95H and is exposed from an upper surface 95T of the cover 95 through the hole 95H.

Specifically, the diameter of the hole 95H of the upper surface 95T of the cover 95 is smaller than the diameter D of the large-diameter ball 94. The diameter of the hole 95H of a lower surface 95B of the cover 95 is larger than the diameter D of the large-diameter ball 94 and is substantially the same as the diameter of the recessed portion 91.

The hole 95H is a tapered hole which is formed such that a diameter of the hole 95H increases in a direction from the upper surface 95T to the lower surface 95B. Moreover, the inner surface of the hole 95H is not in contact with the surface of the large-diameter ball 94. A gap between the inner surface of the hole 95H and the surface of the large-diameter ball 94 is smaller than the diameter of the small-diameter ball 93.

The cover 95 is a member that maintains a state where the large-diameter ball 94 is rotatable and prevents the small-diameter balls 93 and the large-diameter ball 94 from being removed from the ball bearing unit 90. As long as such function of the cover 95 is obtained, the cover 95 is not limited to the configuration shown in FIG. 2A.

A distance G between the heater 20 and the heater base 50 is determined by the height of the base plate B, the height of the pedestal 92, the diameter of the small-diameter ball 93, the diameter of the large-diameter ball 94, and the thickness of the pad 21P.

Note that, as a material used to form the pedestal 92, the small-diameter balls 93, the large-diameter ball 94, and the cover 95, for example, ceramic materials such as alumina are adopted. Materials of members that constitutes the ball bearing unit 90 are not limited to the example shown in the embodiment.

### (Arrangement of Ball Bearing Units)

FIG. 3 is a view showing the plasma CVD apparatus 100 which is projected thereon from a vertical direction and is a plan view for explaining a configuration of the heater 20, the heater base 50, and the ball bearing units 90. Reference numeral 41 represents a support pillar attached to the back surface 51B of the heater base 50, and the electric supply lines 25 that supply electric power to the heater 20 pass through the inside of the support pillar 41 (refer to FIG. 1). Note that, in FIG. 3, the other constituent parts constituting the plasma CVD apparatus 100 are omitted.

As shown in FIG. 3, three ball bearing units 90 are arranged on the upper surface 51T of the heater base 50, that is, on one surface of the heater base 50. In addition, as shown in FIG. 1, since the ball bearing unit 90 is arranged between the heater 20 and the heater base 50 in the vertical direction, the heater 20 is supported by the ball bearing units 90 at three points.

Although the number of the ball bearing units 90 is three in the example shown in FIG. 3, the number thereof may be three or more. As long as the number of the ball bearing units 90 is at least three, the heater 20 is stably supported by the ball bearing units 90 at three points.

Note that, four or more ball bearing units 90 may be arranged on the upper surface 51T of the heater base 50.

Next, an action of the plasma CVD apparatus 100 provided with the heater base 50 including the above-described configuration will be described.

When electric power is supplied to the heater line 24 from the external terminals 44 through the electric supply line 25, the heater 20 is heated. Although a temperature of the heater 20 can be controlled to a suitable temperature, in the embodiment, it is set to a high temperature such as over 380° C. For example, although the heater 20 can be heated at 430° C. or higher, the temperature is appropriately determined depending on the types of film formed on the substrate K, conditions for film formation, or the like.

In a state where the substrate K is mounted on the heater 20 having a temperature set as the mentioned above, a gap between the heater 20 and the upper electrode 75 is adjusted by the lifting mechanism 40. Furthermore, a gas necessary for CVD process is supplied to the inside of the vacuum chamber 10 by the gas supplier 70, the vacuum pump 60 and the pressure adjustment valve are driven to adjust a pressure inside the vacuum chamber 10, high-frequency power (RF) is supplied to the upper electrode 75 by the high-frequency power supply 30, plasma is generated between the heater 20 and the upper electrode 75, and therefore a film is formed on the substrate K.

When the heater 20 is heated as described above, the heater 20 is thermally-expanded. Particularly, due to difference in coefficient of thermal expansion between the constituent materials of the heater 20 and the heater base 50, the heater 20 thermally expands relative to the heater base 50 in the horizontal direction. At this time, since the support surface 21B of the heater 20 is supported by the large-diameter ball 94 that constitutes the ball bearing unit 90 and is rotatable, the heater 20 is displaced (moved) relative to the heater base 50. Since the displacement due to thermal expansion of the heater 20 is converted into rotation of the large-diameter ball 94, friction does not occur between the heater 20 and the heater base 50.

Conventionally, friction is likely to occur at a contact face between a heater and a heater base, the heater is less likely to slide on the heater base, and waviness deformation or warpage deformation due to the friction on the contact face occurred in accordance with thermal expansion the heater in the horizontal direction. Flatness of the top surface of the heater on which such deformation occurs was, for example, approximately 2 mm.

In contrast, as the ball bearing unit 90 is provided in the embodiment, waviness deformation or warpage deformation does not occur on the heater 20. Even in the case where the heater 20 is heated at a high temperature, flatness of the mounting surface 21T of the heater 20 can be ensured, and the flatness thereof can be strictly and easily maintained. For example, a flatness of 0.5 mm can be achieved.

As a result, a gap between the upper electrode 75 and the heater 20 can be maintained constant, the thickness profile of a film on the substrate K can be made uniform by uniformly-generated plasma.

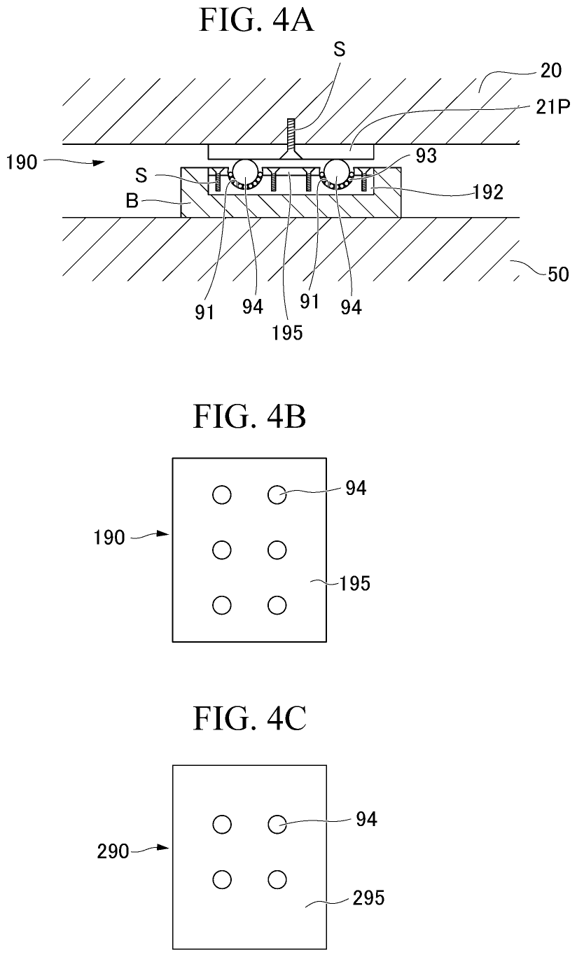

Next, modified examples A, B, C, and D of the ball bearing unit according to the first embodiment will be described with reference to FIGS. 2B, 2C, and 4A to 4C.

In FIGS. 2B, 2C, and 4A to 4C, identical reference numerals are used for the elements which are identical to those of the aforementioned first embodiment, and the explanations thereof are omitted or simplified here.

### Modified Example A of First Embodiment

FIG. 2B is an enlarged cross-sectional view showing the heater 20, heater base 50A, and the ball bearing unit 90 which constitute the processing apparatus according to a modified example A of the first embodiment. The modified example A is different from the first embodiment in configuration of a heater base to which the ball bearing unit 90 is attached.

Specifically, the heater base 50A is provided with an attachment recessed portion 51R that is formed to be recessed from the upper surface 51T. The ball bearing unit 90 is disposed in the attachment recessed portion 51R. The lower surface of the ball bearing unit 90 is in contact with a bottom surface 51L of the attachment recessed portion 51R such that part (base plate B) of the ball bearing unit 90 protrudes from the upper surface 51T. That is, the bottom surface 51L of the attachment recessed portion 51R is part of a surface that constitutes the heater base 50A.

In this configuration, a depth of the attachment recessed portion 51R (the distance from the upper surface 51T to the bottom surface 51L) is not particularly limited. For example, a depth of the attachment recessed portion 51R is appropriately determined in accordance with the distance G between the heater 20 and the heater base 50A and a height of the ball bearing unit 90 (the distance from the contact point of the large-diameter ball 94 and the pad 21P to the back surface of the base plate B). For example, the attachment recessed portion 51R having a depth of approximately 10 mm may be formed on the upper surface 51T of the heater base 50A.

The size (area) of the attachment recessed portion 51R in plan view is slightly larger than the size of the base plate B. The size of the attachment recessed portion 51R is determined such that the side surface of the base plate B can be in contact with an inner wall 51W of the attachment recessed portion 51R when the ball bearing unit 90 is disposed in the attachment recessed portion 51R and such that the ball bearing unit 90 (base plate B) can be easily removed from the attachment recessed portion 51R.

The number of the attachment recessed portions 51R formed on the upper surface 51T is determined depending on the number of the ball bearing units 90.

According to the heater base 50A having the above-described configuration, the position of the ball bearing unit 90 can be fixed only by disposing the ball bearing unit 90 in the attachment recessed portion 51R. In other words, in the positioning configuration, it is not necessary to use a fastening member such as a screw. Since the fastening member is not used, the number of parts which constitute the processing apparatus can be reduced.

Furthermore, when maintenance operation is carried out in a processing apparatus in which the ball bearing unit 90 is attached to the attachment recessed portion 51R in advance, an operator grasps the ball bearing unit 90 and only removes the ball bearing unit 90 from the attachment recessed portion 51R, and therefore maintenance operation can be carried out. In other words, since the fixation configuration that does not use a fastening member is obtained, it is easy to remove the ball bearing unit 90.

Particularly, in the processing apparatus in which there is a concern about corrosion of constituent components thereof, maintenance frequency increases in many cases; however, according to the heater base 50A having the above-mentioned configuration, maintenance becomes easy, and it contributes to a reduction in maintenance time.

### Modified Example B of First Embodiment

FIG. 2C is an enlarged cross-sectional view showing the heater 20, heater base 50B, and the ball bearing unit 90A which constitute the processing apparatus according to a modified example B of the first embodiment. The modified example B is different from the modified example A in configuration of a ball bearing unit.

Specifically, the ball bearing unit 90A is not provided with the base plate B shown in FIGS. 2A and 2B but is configured of the pedestal 92, the small-diameter balls 93, the large-diameter ball 94, and the cover 95.

The heater base 50B is provided with the attachment recessed portion 51R that is formed to be recessed from the upper surface 51T. The ball bearing unit 90A is disposed in the attachment recessed portion 51R. The lower surface of the ball bearing unit 90A is in contact with the bottom surface 51L of the attachment recessed portion 51R such that part (cover 95) of the ball bearing unit 90A protrudes from the upper surface 51T.

In this configuration, a depth of the attachment recessed portion 51R is appropriately determined in accordance with, for example, the distance G between the heater 20 and the heater base 50B and a height of the ball bearing unit 90A (the distance from the contact point of the large-diameter ball 94 and the pad 21P to the back surface of the pedestal 92).

The size (area) of the attachment recessed portion 51R in plan view is slightly larger than the size of the pedestal 92. The size of the attachment recessed portion 51R is determined such that the side surface of the pedestal 92 can be in contact with the inner wall 51W of the attachment recessed portion 51R when the ball bearing unit 90A is disposed in the attachment recessed portion 51R and such that the ball bearing unit 90A (pedestal 92) can be easily removed from the attachment recessed portion 51R.

The number of the attachment recessed portions 51R formed on the upper surface 51T is determined depending on the number of the ball bearing units 90A.

According to the above-described configuration, since the ball bearing unit 90A is not provided with the base plate B but the pedestal 92 is directly attached to the attachment recessed portion 51R, the number of parts which constitute the processing apparatus can be reduced.

Furthermore, similar to the aforementioned modified example A, the position of the ball bearing unit 90A can be fixed only by disposing the ball bearing unit 90A in the attachment recessed portion 51R without using a fastening member. Moreover, it is possible to easily remove the ball bearing unit 90A from the attachment recessed portion 51R.

Particularly, in the processing apparatus in which there is a concern about corrosion of constituent components thereof, maintenance frequency increases in many cases; however, according to the heater base 50B having the above-mentioned configuration, maintenance becomes easy, and it contributes to a reduction in maintenance time.

### Modified Example C of First Embodiment

FIG. 4A is an enlarged cross-sectional view showing a ball bearing unit 190 according to a modified example C of the first embodiment. FIG. 4B is an enlarged plan view showing the ball bearing unit 190 according to the modified example C.

The modified example C is different from the first embodiment in configuration of a ball bearing unit. Specifically, the ball bearing unit 190 includes the base plate B, a pedestal 192 having a plurality of recessed portions 91, the small-diameter balls 93, a plurality of large-diameter balls 94, and a cover 195.

As shown in FIG. 4A, in the modified example C, the number of the recessed portions 91 formed on the pedestal 192 is six, and the number of the large-diameter balls 94 is six. One large-diameter ball 94 is disposed in one recessed portion 91. Also, the number of the holes formed on the cover 195 is six depending on the number of the recessed portions 91.

The pad 21P is in contact with the large-diameter ball 94, and the large-diameter ball 94 can roll on a surface of the pad 21P.

### Modified Example D of First Embodiment

FIG. 4C is an enlarged plan view showing a ball bearing unit 290 according to a modified example D of the first embodiment. The ball bearing unit 290 according to the modified example D is different from the modified example C shown in FIG. 4B in the number of recessed portions and large-diameter balls. The ball bearing units 290 includes four large-diameter balls.

Configurations and materials of the other members constituting the ball bearing units 190 and 290 are the same as those of the ball bearing unit 90 according to the above-mentioned embodiment.

The ball bearing units 190 and 290 according to the aforementioned modified examples C and D are attachable to the heater base 50 instead of the ball bearing units 90 shown in FIGS. 1 and 3.

In this case, since the large-diameter balls 94 are in contact with the pad 21P at a plurality of points for each of the ball bearing units, the heater 20 can be supported by the support points having the number greater than that of the case shown in FIG. 3.

Consequently, a load applied to one large-diameter ball 94 can be reduced less than that of the configuration (FIG. 3) that supports the heater 20 by use of the three ball bearing units 90 shown in FIGS. 2A to 2C. In other words, a load due to the weight of the heater 20 is distributed to the large-diameter balls 94 arranged in each ball bearing unit. According to this result, in addition to the above-mentioned effects, the large-diameter ball 94 is likely to rotate in each ball bearing unit, and in this state, the heater 20 can be displaced (moved) relative to the heater base 50.

Note that, as a plurality of ball bearing units provided in the plasma CVD apparatus 100, the ball bearing units 90, 190, and 290 may be combined and attached to the heater base 50.

In addition, the number of the large-diameter balls 94 provided in the ball bearing unit is not limited to the aforementioned six or four but is appropriately selected in accordance with an arrangement pattern on which the ball bearing units are arranged, a load applied to each ball bearing unit, or the like.

In other cases, the above-described ball bearing units 190 and 290 are also applicable to the configuration shown in FIG. 2B. In this case, the base plate B constituting the above-mentioned ball bearing unit 190 or 290 is disposed in the attachment recessed portion 51R.

Additionally, the pedestal 192 constituting the above-mentioned ball bearing units 190 and 290 is also applicable to the configuration shown in FIG. 2C. In this case, the pedestal 192 is disposed in the attachment recessed portion 51R.

### Second Embodiment

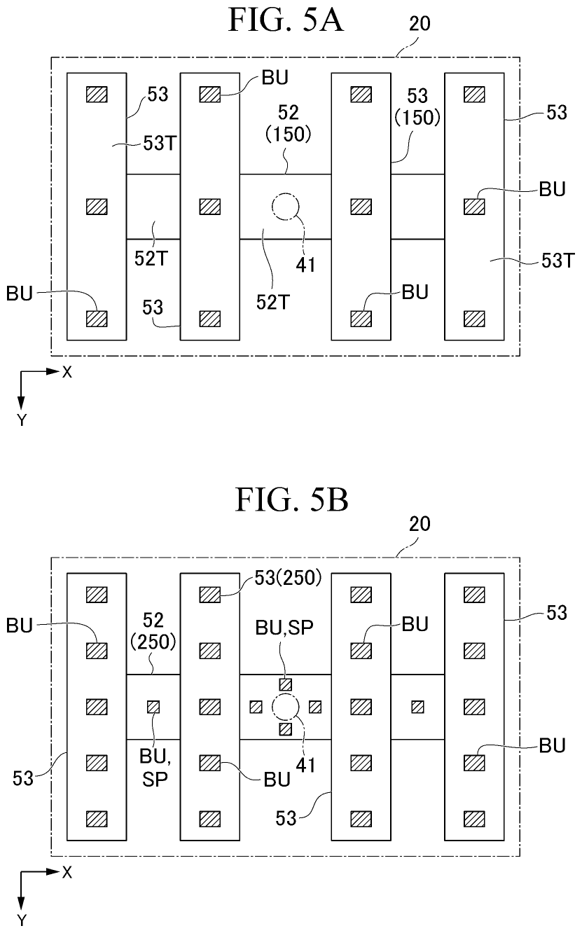

Next, a plasma CVD apparatus according to a second embodiment of the invention and modified examples thereof will be described with reference to FIGS. 5A to 7B.

In FIGS. 5A to 7B, identical reference numerals are used for the elements which are identical to those of the first embodiment, and the explanations thereof are omitted or simplified here. The second embodiment is different from the first embodiment in configuration of a heater base.

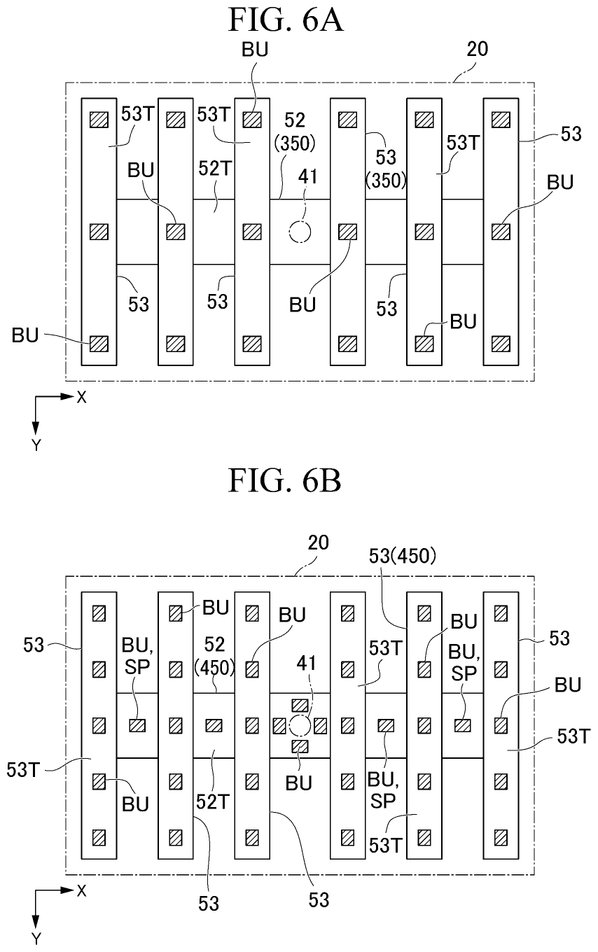

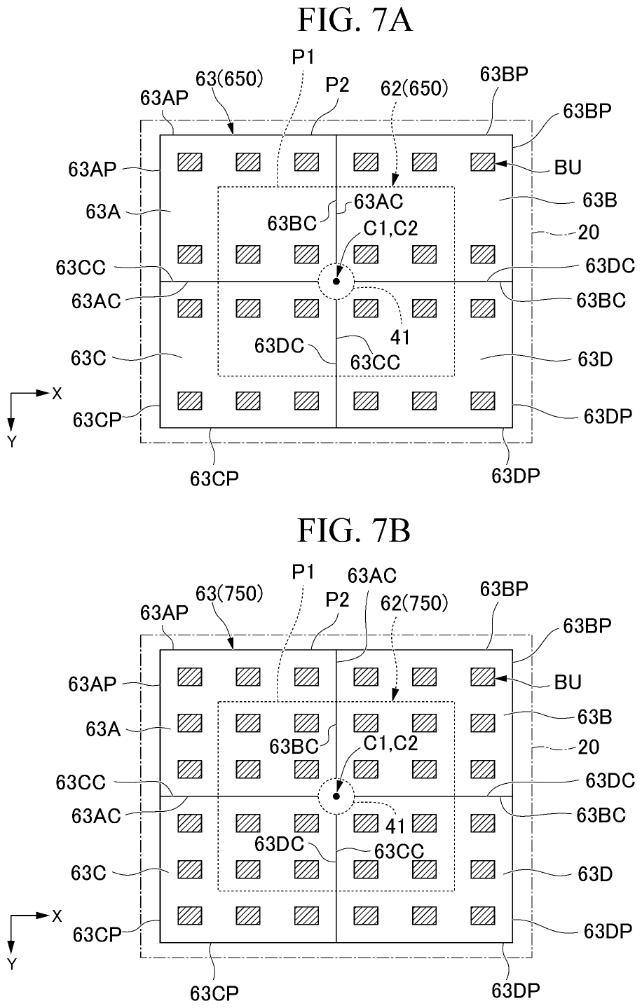

FIGS. 5A to 7B are views showing the plasma CVD apparatus according to the second embodiment of the invention which is projected thereon from a vertical direction and are explanatory diagrams showing an arrangement the heater 20, a heater base 150, and ball bearing units BU which constitute the plasma CVD apparatus. FIG. 5A is a plan view showing the heater base 150 according to the second embodiment. FIG. 5B is a plan view showing a heater base 250 according to a modified example 1. FIG. 6A is a plan view showing a heater base 350 according to a modified example 2. FIG. 6B is a plan view showing a heater base 450 according to a modified example 3. FIG. 7A is a plan view showing a heater base 650 according to a modified example 4. FIG. 7B is a plan view showing a heater base 750 according to a modified example 5.

Note that, in FIGS. 5A to 7B, any one of the above-mentioned ball bearing units 90, 190, and 290 is adopted to the ball bearing unit BU represented by reference letter BU.

As shown in FIG. 5A, the heater base 150 includes a first base 52 that extends in the X-direction (first direction) and a plurality of second bases 53 that extend in the Y-direction (second direction intersecting with the first direction). The second bases 53 are fixed to the first base 52 by fastening members which is not shown in the figure.

In the embodiment, the back surface of one first base 52 is fixed to the support pillar 41, and four second bases 53 are fixed to the upper surface of the first base 52.

Since three ball bearing units BU are arranged on the upper surface 53T of each of the second bases 53, twelve ball bearing units BU in total are arranged on the heater base 150. Note that, in the example shown in FIG. 5A, the ball bearing unit BU is not disposed on the first base 52.

In the case where the heater base 150 having the above-described configuration is applied to the plasma CVD apparatus, since the large-diameter ball 94 is in contact with the pad 21P on each of the ball bearing units BU, the heater 20 can be supported by the support points having the number greater than that of the case shown in FIG. 3.

Accordingly, a load due to the weight of the heater 20 is distributed to the ball bearing units BU, a load applied to one ball bearing unit BU can be reduced. According to this result, in addition to the above-mentioned effects, the large-diameter ball 94 is likely to rotate in each ball bearing unit BU, and in this state, the heater 20 can be displaced (moved) relative to the heater base 150.

### Modified Example 1 of Second Embodiment

In the modified example, identical reference numerals are used for the elements which are identical to those of the heater base 150, and the explanations thereof are omitted or simplified here.

In the modified example 1 shown in FIG. 5B, four second bases 53 are fixed to one first base 52. Five ball bearing units BU are arranged on the upper surface 53T of each of the second bases 53. Furthermore, the ball bearing units BU are arranged not only on the upper surfaces 53T of the second bases 53 but also on the upper surface 52T of the first base 52. Moreover, the ball bearing units BU are also arranged at the position close to the support pillar 41 so as to surround the support pillar 41. Twenty-six ball bearing units BU in total are arranged on the heater base 250.

In addition, in the configuration in which the ball bearing units BU are arranged on the upper surface 52T of the first base 52, a step difference occurs between the upper surface 52T of the first base 52 and the upper surfaces 53T of the second bases 53. That is, since the second base 53 having a thickness is fixed on the first base 52, a step difference corresponding to the thickness of the second base 53 occurs.

In order to solve the step difference, spacers SP, each of which has a thickness corresponding to the height of the step difference (the thickness of the second base 53), are disposed on the upper surface 52T of the first base 52, and the ball bearing units BU are arranged on the spacers SP. That is, the spacer SP is disposed between the ball bearing unit BU and the upper surface 52T.

In the case where the heater base 250 having the above-described configuration is applied to the plasma CVD apparatus, the heater 20 can be supported by the support points having the number greater than that of the case shown in FIG. 5A. For this reason, a load due to the weight of the heater 20 is distributed to the ball bearing units BU, a load applied to one ball bearing unit BU is reduced, the large-diameter ball 94 is likely to rotate in each ball bearing unit BU, and in this state, the heater 20 can be displaced (moved) relative to the heater base 250.

Furthermore, even in the case where a step difference occurs between the upper surface 52T of the first base 52 and the upper surfaces 53T of the second base 53, since the spacers SP are disposed on the upper surface 52T, the distance between the upper surface 52T and the heater 20 can be equal to the distance between the upper surface 53T and the heater 20. Accordingly, flatness of the mounting surface 21T of the heater 20 can be ensured, and the flatness thereof can be strictly and easily maintained. As a result, a gap between the upper electrode 75 and the heater 20 can be maintained constant, a thickness profile of a film on the substrate K can be made uniform by uniformly-generated plasma.

### Modified Example 2 of Second Embodiment

In the modified example, identical reference numerals are used for the elements which are identical to those of the heater bases 150 and 250, and the explanations thereof are omitted or simplified here.

In the modified example 2 shown in FIG. 6A, six second bases 53 are fixed to one first base 52.

Three ball bearing units BU are arranged on the upper surface 53T of each of the second bases 53, and eighteen ball bearing units BU in total are arranged on the heater base 350. Note that, in the example shown in FIG. 6A, the ball bearing unit BU is not disposed on the first base 52.

In the case where the heater base 350 having the above-described configuration is applied to the plasma CVD apparatus, since the large-diameter ball 94 is in contact with the pad 21P on each of the ball bearing units BU, the heater 20 can be supported by the support points having the number greater than that of the case shown in FIG. 3.

### Modified Example 3 of Second Embodiment

In the modified example, identical reference numerals are used for the elements which are identical to those of the heater bases 150, 250, and 350, and the explanations thereof are omitted or simplified here.

In the modified example 3 shown in FIG. 6B, six second bases 53 are fixed to one first base 52. Five ball bearing units BU are arranged on the upper surface 53T of each of the second bases 53. Furthermore, the ball bearing units BU are arranged not only on the upper surfaces 53T of the second bases 53 but also on the upper surface 52T of the first base 52. Moreover, the ball bearing units BU are also arranged at the position close to the support pillar 41 so as to surround the support pillar 41. Thirty-eight ball bearing units BU in total are arranged on the heater base 450.

Additionally, in order to solve the step difference that occurs between the upper surface 52T and the upper surface 53T, the spacers SP corresponding to the thickness of the second bases 53 are arranged on the upper surface 52T. The ball bearing units BU are arranged on the spacers SP.

In the case where the heater base 450 having the above-described configuration is applied to the plasma CVD apparatus, as described above, a load due to the weight of the heater 20 is distributed to the ball bearing units BU, a load applied to one ball bearing unit BU is reduced, the large-diameter ball 94 is likely to rotate in each ball bearing unit BU, and in this state, the heater 20 can be displaced (moved) relative to the heater base 450.

Furthermore, even in the case where a step difference occurs between the upper surface 52T of the first base 52 and the upper surfaces 53T of the second base 53, since the spacers SP are disposed on the upper surface 52T, the distance between the upper surface 52T and the heater 20 can be equal to the distance between the upper surface 53T and the heater 20. As a result, the same effects as the above-mentioned effects are obtained.

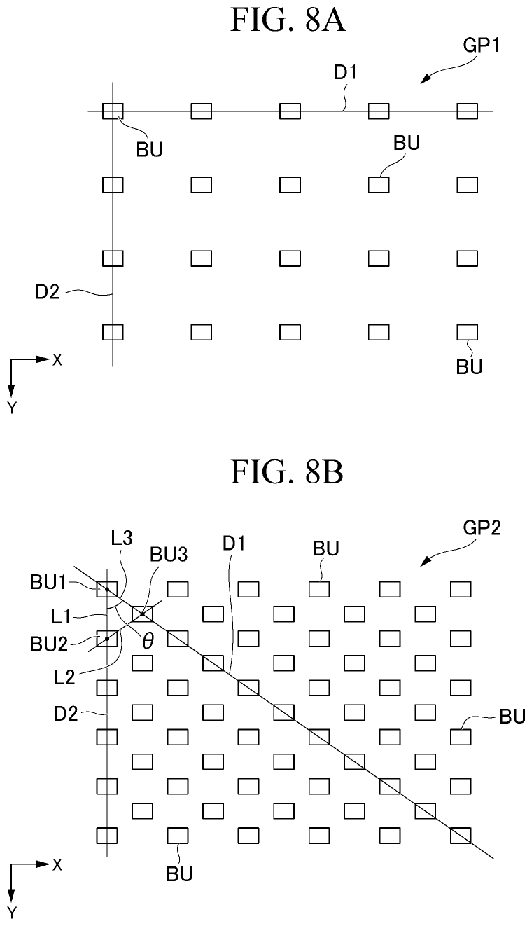

Note that, FIGS. 5A and 5B explain the case where the number of the second bases 53 is four and FIGS. 6A and 6B explain the case where the number of the second bases 53 is six; however, the number of the second bases 53 is not limited to FIGS. 5A to 6B but is appropriately modifiable depending on a width of the second base 53, an arrangement pattern of the ball bearing units BU shown in FIGS. 8A and 8B, or the like (described below).

Moreover, in FIGS. 5A to 6B, the shapes of the first base 52 and the second bases 53 are each an elongated rectangular shape; however, the invention is not limited to the shape in which six second bases 53 are on the first base 52. Moreover, the aforementioned embodiment shows the configuration in which the second bases 53 are stacked on and fixed to the first base 52; however, the invention is not limited to the fixation configuration of the first base 52 and the second bases 53.

In the above-mentioned second embodiment and the modified examples 1 to 3 thereof, the extending direction of the first base 52 (X-direction) intersects with the extending directions of the second bases 53 (Y-direction); however, the invention is not limited to the configuration in which the first base 52 and the second base 53 intersect with each other. For example, configurations shown in modified examples 4 and 5 which will be described below may be adopted.

### Modified Example 4 of Second Embodiment

A heater base 650 according to the modified example 4 shown in FIG. 7A has a configuration in which a flat plate-shaped first base 62 and a second base 63 larger than the first base 62 are stacked on the support pillar 41. Specifically, the first base 62 and the second base 63 are integrally fastened to the support pillar 41. The second base 63 is not fixed to the first base 62 at the portion other than the portion at which the support pillar 41 is disposed, and the second base 63 is in a state of being simply mounted on the upper surface of the first base 62.

When seen in a plan view of the heater base 650, the center C2 of the second base 63 coincides with the center C1 of the first base 62, the second base 63 is fixed to the upper surface of the first base 62 so as to cover the entire surface of the first base 62. Note that, the center C1 of the first base 62 and the center C2 of the second base 63 are the portions through which the electric supply lines 25 provided inside the support pillar 41 pass, and therefore the centers C1 and C2 correspond to the portion that is cut out in a circular shape (virtual center). Additionally, the second base 63 has an outer-periphery P2 located outside an outer-periphery P1 of the first base 62. Here, the outer-periphery P1 of the first base 62 corresponds to the side surface on the outer-periphery of the first base 62. Similarly, the outer-periphery P2 of the second base 63 corresponds to the side surface on the outer-periphery of the second base 63.

The second base 63 includes a plurality of a flat plate-shaped base separated body (four base separated bodies, first separated body 63A, second separated body 63B, third separated body 63C, and fourth separated body 63D). Each of the base separated bodies is fixed to the upper surface of the first base 62.

The outer-periphery of each of the base separated bodies forms the outer-periphery P2 of the second base 63. That is, the outer-periphery P2 is formed by the outer-periphery 63AP of the first separated body 63A, the outer-periphery 63BP of the second separated body 63B, the outer-periphery 63CP of the third separated body 63C, and the outer-periphery 63DP of the fourth separated body 63D.

Each of the base separated bodies has an opposed face facing an adjacent base separated body. That is, the first separated body 63A has two opposed faces 63AC, one of the opposed faces 63AC faces the second separated body 63B, and the other of the opposed faces 63AC faces the third separated body 63C. The second separated body 63B has two opposed faces 63BC, one of the opposed faces 63BC faces the first separated body 63A, and the other of the opposed faces 63BC faces the fourth separated body 63D. The third separated body 63C has two opposed faces 63CC, one of the opposed faces 63CC faces the first separated body 63A, and the other of the opposed faces 63CC faces the fourth separated body 63D. The fourth separated body 63D has two opposed faces 63DC, one of the opposed faces 63DC faces the second separated body 63B, and the other of the opposed faces 63DC faces the third separated body 63C.

The above-described four base separated bodies 63A, 63B, 63C, and 63D are arranged such that a space does not occur between the opposed faces facing each other, that is, such that the opposed faces facing each other are in contact with each other.

Six ball bearing units BU are arranged on the upper surface of each of the base separated bodies. Accordingly, twenty-four ball bearing units BU in total are arranged on upper surface of the second base 63 formed of the four base separated bodies.

In the case where the heater base 650 having the above-described configuration is applied to the plasma CVD apparatus, the heater 20 can be supported by the support points having the number greater than that of the case shown in FIG. 3. In addition, a load due to the weight of the heater 20 is distributed to the ball bearing units BU, a load applied to one ball bearing unit BU can be reduced. As a result, the large-diameter ball 94 is likely to rotate in each ball bearing unit BU, and in this state, the heater 20 can be displaced (moved) relative to the heater base 650.

Furthermore, since the second base 63 is formed by arranging the four base separated bodies 63A, 63B, 63C, and 63D such that a space does not occur between the opposed faces facing each other, heat generated from the heater 20 is prevented from being radiated toward the lower side of the second base 63 through a space between the base separated bodies. Consequently, it is possible to improve thermal insulation due to the second base 63 and uniformity in temperature on the surface of the heater 20 can be maintained. As a result, the heater 20 can uniformly heat the substrate K and therefore, it is possible to obtain uniformity in film formation. Particularly, in a high-temperature process (for example, at a high temperature such as over 380° C.), it is possible to obtain excellent uniformity in film formation.

### Modified Example 5 of Second Embodiment

In the modified example, identical reference numerals are used for the elements which are identical to those of the heater base 650, and the explanations thereof are omitted or simplified here.

In a heater base 750 according to the modified example 5 shown in FIG. 7B, nine ball bearing units BU are arranged on the upper surface of each of the four base separated bodies 63A, 63B, 63C, and 63D. Accordingly, thirty-six ball bearing units BU in total are arranged on upper surface of the second base 63 formed of the four base separated bodies.

In the case where the heater base 750 having the above-described configuration is applied to the plasma CVD apparatus, the heater 20 can be supported by the support points having the number greater than that of the case shown in FIG. 7A. In addition, a load due to the weight of the heater 20 is distributed to the ball bearing units BU, a load applied to one ball bearing unit BU can be reduced. As a result, the large-diameter ball 94 is likely to rotate in each ball bearing unit BU, and in this state, the heater 20 can be displaced (moved) relative to the heater base 750.

Moreover, similar to the heater base 650 shown in FIG. 7A, due to improvement in thermal insulation by the second base 63, uniformity in temperature on the surface of the heater 20 can be maintained. As a result, the heater 20 can uniformly heat the substrate K and therefore, it is possible to obtain uniformity in film formation. Particularly, in a high-temperature process (for example, at a high temperature such as over 380° C.), it is possible to obtain excellent uniformity in film formation.

### Modified Examples 6 and 7 of Second Embodiment

Next, an arrangement pattern that is formed by a plurality of the ball bearing units BU arranged on the above-described heater bases 150, 250, 350, 450, 650, and 750 will be described.

FIGS. 8A and 8B are each an explanatory diagram showing a plane pattern of the ball bearing units when seen in a plan view of the heater base constituting the processing apparatus according to the second embodiment of the invention. FIG. 8A shows a modified example 6 and FIG. 8B shows a modified example 7.

Note that, in FIGS. 8A and 8B, a heater base is not shown but an arrangement (array) of the ball bearing units BU arranged on a heater base is only explained. As the configuration of the heater base, configurations shown in FIGS. 3 and 5A to 7B or the like are adopted.

In the modified example 6 shown in FIG. 8A, a plurality of the ball bearing units BU (four or more ball bearing units BU) are arrayed so as to form a grid pattern GP1 that is arrayed along a first array direction D1 (X-direction) and a second array direction D2 (Y-direction, a second array direction intersecting with the first array direction).

Particularly, the first array direction D1 orthogonally intersects with the second array direction D2, and the ball bearing unit BU is arranged at the intersection point of the first array direction D1 and the second array direction D2.

In the modified example 7 shown in FIG. 8B, a plurality of the ball bearing units BU (four or more ball bearing units BU) are arrayed so as to form a grid pattern GP2 that is arrayed along the first array direction D1 (a direction in which the first array direction D1 is inclined with respect to the second array direction D2 at an angle θ) and the second array direction D2.

That is, the first array direction D1 obliquely intersects with the second array direction D2. The ball bearing unit BU is arranged at the intersection point of the first array direction D1 and the second array direction D2.

In other words, the ball bearing units BU are arranged on the heater base so as to form a staggered pattern.

Additionally, when focusing attention on three ball bearing units BU1, BU2, and BU3 which are adjacent to each other on the grid pattern GP2, three distances L1, L2, and L3 are determined by the ball bearing units Bill, BU2, and BU3. The distance L1 is a distance between the ball bearing units Bill and BU2. The distance L2 is a distance between the ball bearing units BU2 and BU3. The distance L3 is a distance between the ball bearing units BU3 and Bill.

In the grid pattern GP2, of the three distances L1, L2, and L3, at least two distances are equal to each other. As such pattern, for example, the case is adopted where the distance L2 is equal to the distance L3 and the distance L1 is different from the distances L2 and L3. In other words, a plurality of ball bearing units are arranged at the pattern such that the ball bearing units are each located at the three corners of an isosceles triangle.

Also, a plurality of ball bearing units may be arranged at a pattern such that the distances L1, L2, and L3 are all equal to each other, in other words, at a pattern such that the ball bearing units are each located at the three corners of an equilateral triangle.

In the configuration in which a plurality of the ball bearing units BU are arranged on the heater base so as to have the grid patterns GP1 and GP2, the aforementioned effects are also obtained.

Note that, as examples of the arrangement patterns of the ball bearing units BU, patterns shown in FIGS. 8A and 8B were described; however, the invention is not limited to the arrangement pattern of the ball bearing units BU. The ball bearing units BU are not necessarily required to be arranged at an equal distance but a plurality of the ball bearing units BU may be arranged on a heater base at a combination pattern in which two or more kinds of regular arrangement patterns are combined.

### Third Embodiment

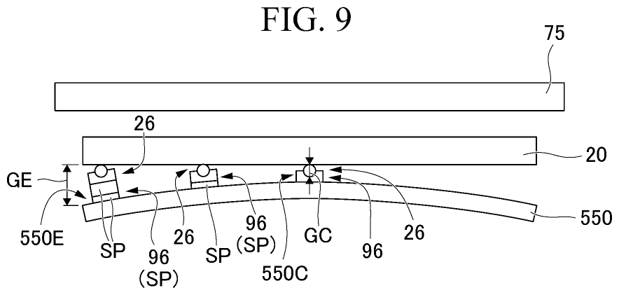

Next, a plasma CVD apparatus according to a third embodiment of the invention will be described with reference to FIG. 9.

In FIG. 9, identical reference numerals are used for the elements which are identical to those of the first embodiment and the second embodiment, and the explanations thereof are omitted or simplified here. The third embodiment is different from the first embodiment and the second embodiment in configuration of a heater base.

The plasma CVD apparatus according to the third embodiment of the invention includes a heater base 550. A plurality of the ball bearing units BU are arranged on a surface of the heater base 550. The heater 20 supported by a plurality of the ball bearing units BU are arranged above the heater base 550. The heater 20 faces the upper electrode 75.

The heater base 550 includes a plurality of distance adjusters 96 on the surface of the heater base 550. One ball bearing unit BU is arranged at one distance adjuster 96. For each of the distance adjusters 96, a distance between the heater base 550 and the contact portion 26 (pad 21P) at which the large-diameter ball 94 is in contact with the heater 20 is adjusted. For example, the spacer SP is not provided on the surface of the center region 550C of the heater base 550 on the distance adjuster 96, the spacer SP is provided on the outer-peripheral region 550E, and therefore the distances GE and GC between the distance adjusters 96 and the heater 20 are determined. Here, the distance GE is determined by adjusting heights of the spacers SP or the number of the spacers SP (the number of pieces).

Note that, a recessed portion having a depth may be formed on the distance adjuster 96 of the center region 550C, and the spacer SP may be disposed in the recessed portion.

The distance GE between the heater 20 and the distance adjuster 96 located at the outer-peripheral region 550E on the surface of the heater base 550 is determined to be greater than the distance GC between the heater 20 and the distance adjuster 96 located at the center region 550C on the surface of the heater base 550. Consequently, even in the case where deflection occurs on the heater base 550, flatness of the mounting surface 21T of the heater 20 supported by the ball bearing units BU is ensured.

Particularly, in recent years, a plasma CVD apparatus becomes larger in size, the areas of the heater and the heater base which constitute the plasma CVD apparatus also increases, and the heater base is slightly flexurally deformed such that it droops in a direction from the center region of the heater base to the outer-peripheral region thereof.

In this case, the heater supported by the heater base with ball bearing units interposed therebetween is also deformed in the direction from the center region to the outer-peripheral region. In accordance with the deformation of the heater, flatness of the top surface of the heater is degraded, a gap between the upper electrode facing the heater and the heater becomes non-uniform, and therefore there is a problem in that a uniform thickness profile is not obtained.

In contrast, in the embodiment, an deflection amount of the heater base 550 on the outer-peripheral region 550E is measured in advance, the distance between the contact portion 26 and the heater base 550 is determined on the distance adjuster 96 so that the distance GE becomes larger than the distance GC in accordance with the deflection amount. Accordingly, even in the case where deflection occurs on the heater base 550, flatness of the mounting surface 21T of the heater 20 supported by the ball bearing units BU can be ensured, and the flatness thereof can be strictly and easily maintained. For example, a flatness of 0.5 mm can be achieved.

Note that, in the case where the distance adjusters 96 are applied to the heater base including the attachment recessed portion 51R shown in FIGS. 2B and 2C, the spacer SP is provided on the attachment recessed portion 51R formed on the outer-peripheral region 550E without providing the spacer SP on the attachment recessed portion 51R formed on the surface of the center region 550C of the heater base. Consequently, the distances GE and GC between the distance adjusters 96 and the heater 20 are determined on the heater base on which the attachment recessed portion 51R is formed.

As described above, while preferred embodiments of the invention have been described and shown above, it should be understood that these are exemplary of the invention and are not to be considered as limiting. Additions, omissions, substitutions, and other modifications can be made without departing from the scope of the invention. Accordingly, the invention is not to be considered as being limited by the foregoing description, and is only limited by the scope of the appended claims.

In the aforementioned embodiments and modified examples, the examples were explained in which the processing apparatus of the invention is applied to the plasma CVD apparatus (film formation apparatus); however, the processing apparatus of the invention is not limited to a plasma CVD apparatus. The processing apparatus of the invention is applicable to an etching apparatus, an ashing apparatus, or the like which are known as a vacuum processing apparatus. Furthermore, the processing apparatus of the invention is not limited to a vacuum processing apparatus but is also applicable to an atmospheric pressure processing apparatus.

In the aforementioned embodiments and modified examples, the examples were described in which a ball bearing unit which is an example of a displacement mechanism is applied to a plasma CVD apparatus; however, the displacement mechanism is not limited to a ball bearing unit. The displacement mechanism may be a roller unit that includes a roller capable of displacing the heater 20 with respect to the heater base 50 in a state being in contact with the heater 20.

In the case of the roller unit, for example, a configuration is adopted in which a shaft attached to the roller is rotatably supported via a bearing. Additionally, a configuration may be adopted which includes: a plurality of small-diameter rollers that roll on a surface a pedestal having a recessed portion; and a large-diameter roller that is rotatably supported by the small-diameter rollers, is in contact with the heater 20, and has a diameter larger than that of the small-diameter roller.

In the aforementioned embodiments and modified examples, the example were described in which the heater lines 24 (heat source) are provided inside the heater 20 and the heater 20 is self-heated by supply of electrical power to the heater line 24; however, the invention is not limited to the configuration in which a heat source is provided inside the heater. For example, a configuration may be adopted in which a heat source is provided outside a heater and the external heat source heats the heater. As the external heat source, a lamp heater provided at a position apart from the heater, a band heater provided to cover the outside of the heater, or the like, is adopted.

In the aforementioned embodiments and modified examples, the effects were described that, in the case where a thermal load such that a temperature of the heater 20 exceeds 380° C. is applied to the heater 20, waviness or warpage of the heater due to thermal expansion is prevented and flatness the heater can be maintained. However, the heater base of the invention is also applicable to a processing apparatus in which a temperature of the heater 20 does not exceed 400° C., and also even in the case where a temperature of the heater 20 is a low temperature, the heater base of the invention is applicable thereto.

The aforementioned distance adjuster 96 is also applicable to the heater bases 50, 150, 250, 350, 450, 650, and 750 shown in FIGS. 3, 5A, 5B, 6A, 6B, 7A, and 7B.

### INDUSTRIAL APPLICABILITY

The invention is widely applicable to a heater base that prevents waviness or warpage of a heater and can maintain flatness of the heater and a processing apparatus provided with the heater base.

### DESCRIPTION OF REFERENCE NUMERALS

10 vacuum chamber, 11 lower chamber, 12 upper chamber, 13 electrode flange, 20 heater, 21B support surface (back surface), 21P pad, 21T mounting surface (top surface), 22 opening hole, 23 lift pin, 24 heater line, 25 electric supply line, 26 contact portion, 30 high-frequency power supply, 40 lifting mechanism, 41 support pillar, 42 flange, 43 bellows, 44 external terminal, 45 lift pin base, 50, 50A, 50B, 150, 250, 350, 450, 550, 650, 750 heater base, 51B back surface, 51T upper surface, 51R attachment recessed portion, 52, 62 first base, 52T upper surface, 51L bottom surface, 51W inner wall, 53, 63 second base, 53T upper surface, 60 vacuum pump, 63A first separated body (base separated body), 63B second separated body (base separated body), 63C third separated body (base separated body), 63D fourth separated body (base separated body), 70 gas supplier, 75 upper electrode, 80 door valve, 90, 90A, 90B, 190, 290, BU, BU1, BU2, BU3 ball bearing unit (displacement mechanism), 91 recessed portion, 92, 192 pedestal, 92T upper surface, 93 small-diameter ball, 94 large-diameter ball, 95, 195, 295 cover, 95B lower surface, 95H hole, 95T upper surface, 96 distance adjuster, 100 plasma CVD apparatus, 550C center region, 550E outer-peripheral region, B base plate, B1 container, GP1, GP2 grid pattern, K substrate, L1, L2, L3 distance, S fastening member, SP spacer.

What is claimed is:

1. A heater base that supports a heater, comprising:
a plurality of displacement mechanisms that are arranged between the heater and the heater base and are provided on the heater base, wherein
of the displacement mechanisms, three or more displacement mechanisms are capable of displacing the heater with respect to the heater base in a state of being in contact with the heater.

2. The heater base according to claim 1, wherein
each of the displacement mechanisms comprises:
a pedestal that is fixed to the heater base and has a recessed portion, the recessed portion opening toward the heater;
a plurality of small-diameter balls that are located inside the recessed portion and roll on a surface of the recessed portion; and
a large-diameter ball that is rotatably supported by the small-diameter balls inside the recessed portion, is in contact with the heater, and has a diameter larger than that of the small-diameter ball.

3. The heater base according to claim 2, wherein
each of the displacement mechanisms comprises:
a plurality of the recessed portions; and
a plurality of the large-diameter balls, wherein
one large-diameter ball is disposed in one recessed portion.

4. The heater base according to claim 1, wherein
the displacement mechanisms are arranged on one surface of the heater base.

5. The heater base according to claim 1, wherein
the heater base comprises:
a first base that extends in a first direction; and
a plurality of second bases that extend in a second direction intersecting with the first direction and are fixed to the first base, wherein
the displacement mechanisms are arranged on the second bases.

6. The heater base according to claim 5, wherein
the displacement mechanism is arranged on the first base.

7. The heater base according to claim 1, wherein
the heater base comprises:
a flat plate-shaped first base; and
a flat plate-shaped second base that has a center coinciding with a center of the first base when seen in a plan view of the heater base, has an outer-periphery located outside an outer-periphery of the first base, is disposed on an upper surface of the first base so as to cover an entire surface of the first base, and is configured of a plurality of base separated bodies, wherein
the displacement mechanisms are arranged on the base separated bodies.

8. The heater base according to claim 1, wherein
the heater base includes a plurality of distance adjusters on a surface of the heater base on which the displacement mechanisms are arranged,
one displacement mechanism is disposed on one distance adjuster,
a distance between a contact portion at which the displacement mechanism is in contact with the heater and the heater base is adjusted for each of the distance adjusters.

9. The heater base according to claim 8, wherein
a distance between the distance adjuster located at an outer-peripheral region of the surface of the heater base and the heater is determined to be greater than a distance between the distance adjuster located at a center region of the surface and the heater.

10. The heater base according to claim 8, further comprising:
a spacer provided on the distance adjuster, wherein
a distance between the distance adjuster and the heater is determined in accordance with a height of the spacer.

11. A processing apparatus that processes a substrate, comprising:
a chamber;
a heater that has a top surface on which the substrate to be mounted and a back surface on a side opposite to the top surface and is disposed inside the chamber;
a heater base that supports the back surface of the heater and is disposed inside the chamber;
a plurality of displacement mechanisms that are arranged between the heater and the heater base and are provided on the heater base;
a high-frequency power supply that generates plasma inside the chamber; and
a lifting mechanism that moves the heater base in a vertical direction, wherein of the displacement mechanisms, three or more displacement mechanisms are capable of displacing the heater with respect to the heater base in a state of being in contact with the heater.

12. The heater base according to claim 5, wherein
the heater base includes a plurality of distance adjusters on a surface of the heater base on which the displacement mechanisms are arranged,
one displacement mechanism is disposed on one distance adjuster,
a distance between a contact portion at which the displacement mechanism is in contact with the heater and the heater base is adjusted for each of the distance adjusters.

13. The heater base according to claim 12, wherein
a distance between the distance adjuster located at an outer-peripheral region of the surface of the heater base and the heater is determined to be greater than a distance between the distance adjuster located at a center region of the surface and the heater.

14. The heater base according to claim 12, further comprising:
a spacer provided on the distance adjuster, wherein
a distance between the distance adjuster and the heater is determined in accordance with a height of the spacer.

15. The heater base according to claim 7, wherein
the heater base includes a plurality of distance adjusters on a surface of the heater base on which the displacement mechanisms are arranged,
one displacement mechanism is disposed on one distance adjuster,
a distance between a contact portion at which the displacement mechanism is in contact with the heater and the heater base is adjusted for each of the distance adjusters.

16. The heater base according to claim 15, wherein
a distance between the distance adjuster located at an outer-peripheral region of the surface of the heater base and the heater is determined to be greater than a distance between the distance adjuster located at a center region of the surface and the heater.

17. The heater base according to claim 15, further comprising:
a spacer provided on the distance adjuster, wherein
a distance between the distance adjuster and the heater is determined in accordance with a height of the spacer.
